(19) United States
(12) Patent Application Publication
(10) Pub. No.: US 2010/0091999 A1
(43) Pub. Date: Apr. 15, 2010

(54) System and Method of Limiting Exposure to Acoustic Noise

(75) Inventor: Nathaniel M. Napoletano, Akron, OH (US)

Correspondence Address: Husch Blackwell Sanders, LLP;Husch Blackwell Sanders LLP Welsh & Katz, 120 S RIVERSIDE PLAZA, 22ND FLOOR, CHICAGO, IL, 60606, US

(73) Assignee: Lockheed Martin Corporation

(21) Appl. No.: 12/252,069

(22) Filed: Oct. 15, 2008

(51) Int. Cl. H03G 3/20

(52) U.S. Cl. 381/57

(57) ABSTRACT

A simulation system incorporates an audio output port to which a user's headset can be coupled. The headset incorporates an output transducer. The system includes a limiter of audio output energy which automatically limits the audio output energy which is coupled to the output transducer to a predetermined maximum dosage per time interval.

### FIELD

The invention pertains to vehicular simulators. More particularly, the invention pertains to simulators were the student or trainee may be exposed to excessive levels of acoustic energy during a simulation.

### BACKGROUND

U.S. limits for noise exposure are contained in OSHA Standard 29 CFR 1910.95 Occupational Noise Exposure. The purpose of this standard is to set limits designed to prevent hearing loss due to occupational noise exposure.

One situation where noise exposure is an issue is in training to use various types of vehicles by using corresponding types of vehicular simulators. Examples include flight simulators as well as simulators of various types of land vehicles such as tanks, trucks, troop transport vehicles and the like.

In order to provide adequate fidelity for training the communications systems of such simulators are usually designed to produce transient acoustical energy within the limits set by the above standard. This same equipment when malfunctioning or abused could produce sustained acoustical energy in excess of the limits set by the above standard. Historically, the responsibility for student, trainee, safety has been placed upon the student and instructor. Under some conditions including user neglect a potentially harmful situation can result.

There is a need to limit excess acoustical energy without having to rely on the student or the instructor paying sufficient attention so as to protect the student from injury. Preferably limiting the excess energy will not interfere with the training activity nor distract from the realism of the simulation.

It would also be desirable to impose limits on the excess energy without substantially impacting the cost of the respective simulator.

### BRIEF DESCRIPTION OF THE DRAWINGS

FIG. 1 is a system diagram of a first embodiment of the invention;

FIG. 2 is a block diagram illustrating additional details of the system of FIG. 1;

FIG. 3 is a system diagram of a second embodiment of the invention;

FIG. 4 is a system diagram of another embodiment of the invention;

FIG. 5 is a block diagram illustrating additional details of the system of FIG. 4; and

FIG. 6 is a system diagram of yet another embodiment of the invention.

### DETAILED DESCRIPTION

While embodiments of this invention can take many different forms, specific embodiments thereof are shown in the drawings and will be described herein in detail with the understanding that the present disclosure is to be considered as an exemplification of the principles of the invention, as well as the best mode of practicing same, and is not intended to limit the invention to the specific embodiment illustrated.

The present invention, which can be embodied in executable software recorded on a computer readable medium, or, in a device, provides a substantially failsafe processing solution that takes the users', the instructor, and the student's compliance out of the loop. Such embodiments will monitor the cumulative sound energy delivered, or expected to be delivered, to the student through his/her communications headset and make the necessary adjustments to the earphone signal's amplitude. This embodiment can also record the magnitude of the student's exposure for forensic purposes.

Embodiments of the invention include an electronic circuit having a microprocessor and associated control software. The circuit will measure the accumulated amount of sound energy, or dose, delivered to the student pilot. If the student pilot is approaching the maximum level of sound energy to which an individual is limited within a training session the circuit will gradually and imperceptibly reduce the communication channel's loudness so as to protect the student.

Under extreme but unusual circumstances the circuit will limit the acoustical sound pressure delivered to the student to 82 dBA (below OSHA's action level) if the student has already received his maximum dose. In one embodiment, the device can be incorporated into student headsets.

Embodiments of the invention are advantageous in that the student is unaware of the device, and the student cannot forget to use the device while training. Embodiments of the invention are especially advantageous in that student safety is not dependent on the subjective judgment of trainers or operators. Embodiments of the invention can measure a student's exposure to hazardous energy precisely and correct the situation while automatically providing a real-time record of the magnitude of the student's exposure.

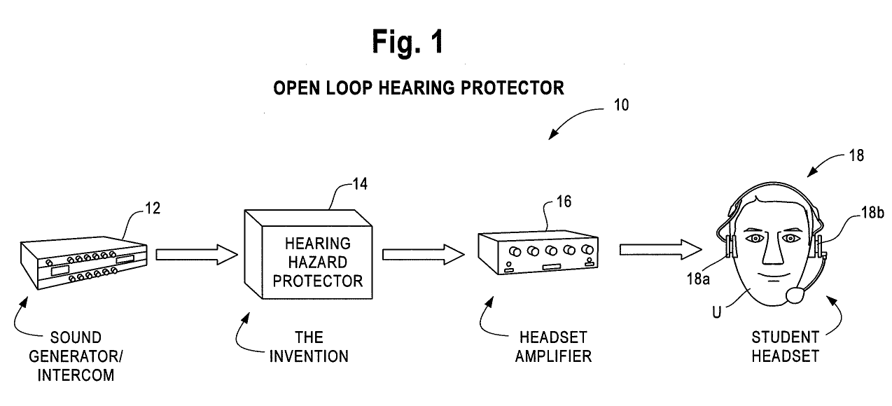

FIG. 1 illustrates an open loop system 10 which embodies the invention. System 10 would be incorporated into or part of a vehicular simulator.

System 10 includes a sound generator 12 which is coupled to a hearing hazard protector 14, discussed in more detail subsequently. Protector 14 is in turn coupled to an amplifier 16 which feeds amplified audio to a headset 18 of a student or user U. Student U would be participating in a training exercise using the vehicular simulation.

Headset 18 includes first and second earphones 18a, b each of which includes an audio output transducer. Protector 14 automatically limits the signals from amplifier 16 which are coupled to earphones 18a,b to protect the student or user U. Output sound dosage, from earphones 18a, b is determined by hearing hazard protector 14 based on signal level from generator 12.

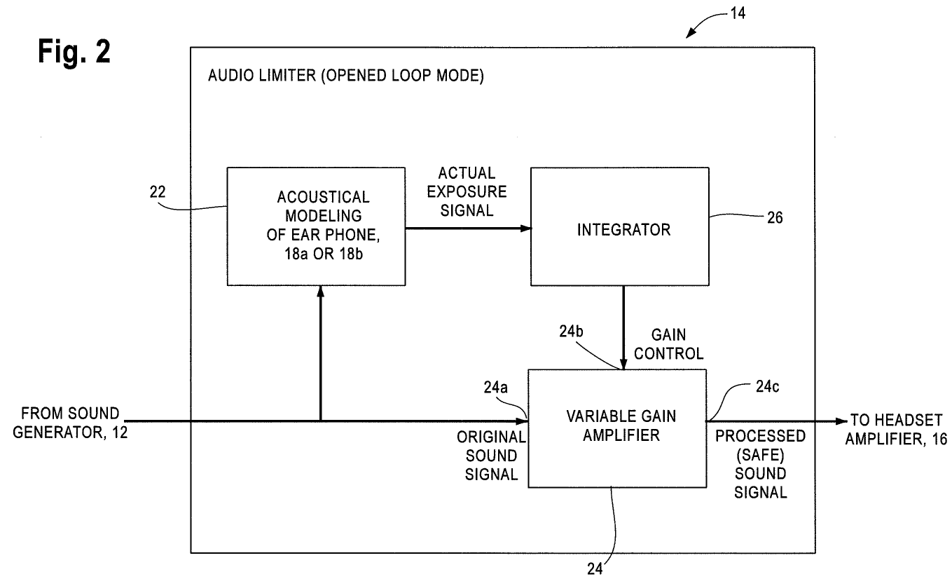

FIG. 2 illustrates an exemplary block diagram of hearing protector 14. Signals from generator 12 are coupled to modeling circuitry 22 and to an input port 24a of a variable gain amplifier 24.

Outputs from the modeling circuitry 22 are coupled to integrator circuitry 26. An integrated gain control signal is coupled to a gain input 24b of amplifier 24. The limited, safe, sound signal is coupled from an output port 24c to amplifier 16. It will be understood that the block diagram 14 of FIG. 2 could be implemented of hard wired circuitry, or as a programmable processor and associated control circuitry recorded on a computer readable medium, all without limitation.

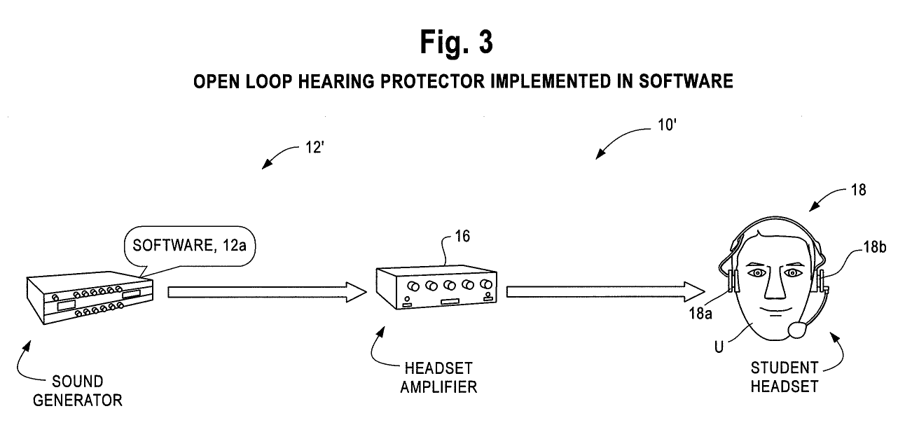

FIG. 3 illustrates an alternate open loop system 10′ in accordance with the invention. In system 10′, the protector 14 has been incorporated into generator 12′ and implemented as software 12a. Output signals from generator 12′, coupled to amplifier 16, are limited to sound signals safe to be amplified and coupled to earphones 18a, b of the student or user U. System 10′ can also be used with a loud speaker as the output audio transducer.

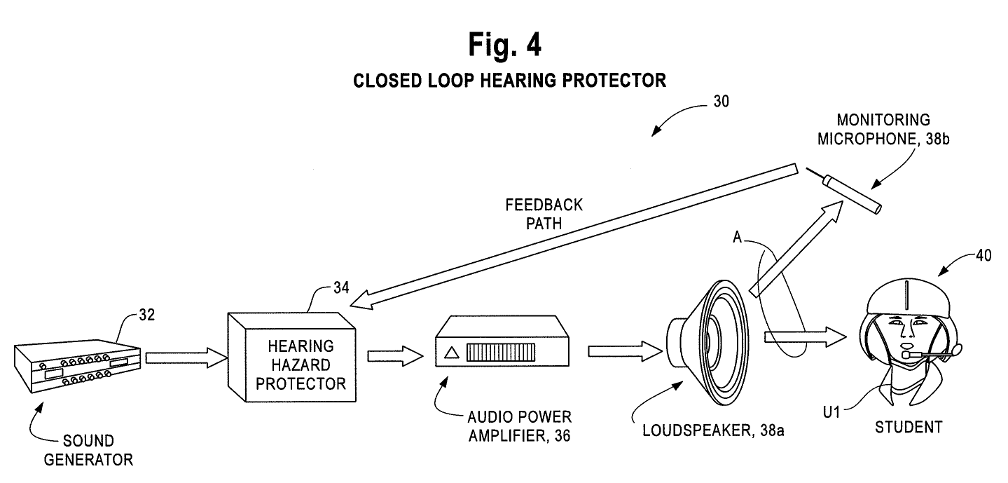

FIG. 4 illustrates an alternate closed loop system 30. In system 30, a sound generator 32 is coupled to a hazard protector 32 which in turn drives an amplifier 36. An output from amplifier 36 in turn drives a loud speak 38a, which would be part of a vehicular simulator. Audio A, from speaker 38a can in turn be directed to student or user U1.

Feedback can be provided to hearing protector 34 via microphone 38b. The protector 34 can determined the sound dosage of student U1 based on monitored sound pressure, as indicated by signals from microphone 38b. System 30 is also advantages in that with the feedback signals, compensation is automatically provided for the acoustical behavior of the simulation system. Further no calibration is required.

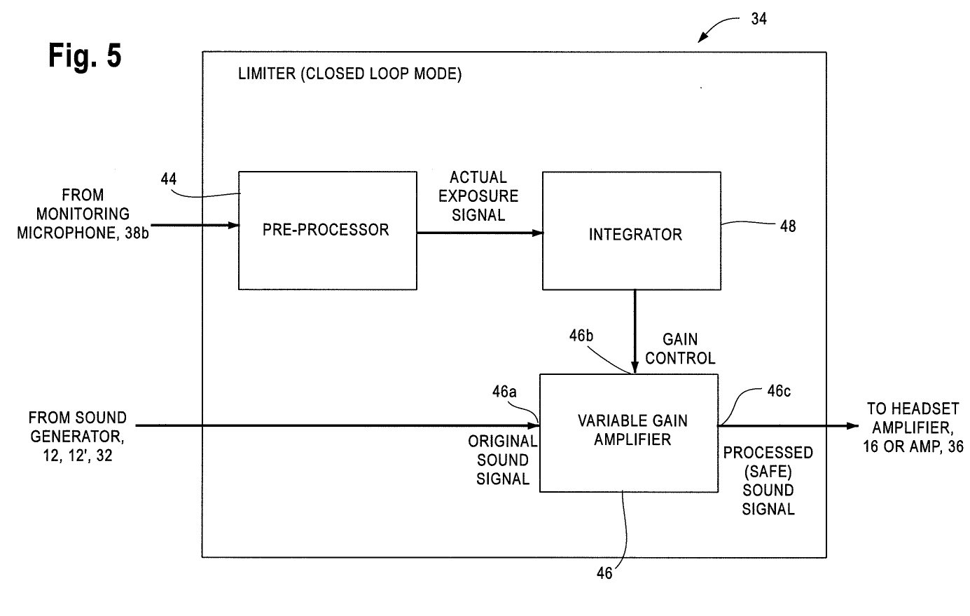

FIG. 5 illustrates a block diagram of hearing protector 34. It will be understood that with a feedback element such as microphone 38b, feedback signals can be provided in any of systems 10, 10′ or 30. In element 34, feedback signals from microphone 38b can be coupled to pre-processing circuitry 44. Signals from generator 12, 12′ or 32 can be coupled to an input port 46a of a variable gain amplifier 46.

Preprocessed signals from circuitry 44 can in turn be coupled to integration circuitry 48. Output integrated gain control signals can be coupled to a port 46b to control the gain of amplifier 46.

Processed, safe sound signals, emitted from port 46c can be coupled to amplifier 16 or 36 depending on the system where element 34 has been installed. It will be understood that element 34 can be implemented in hardware or software or both without limiting the scope of the present invention.

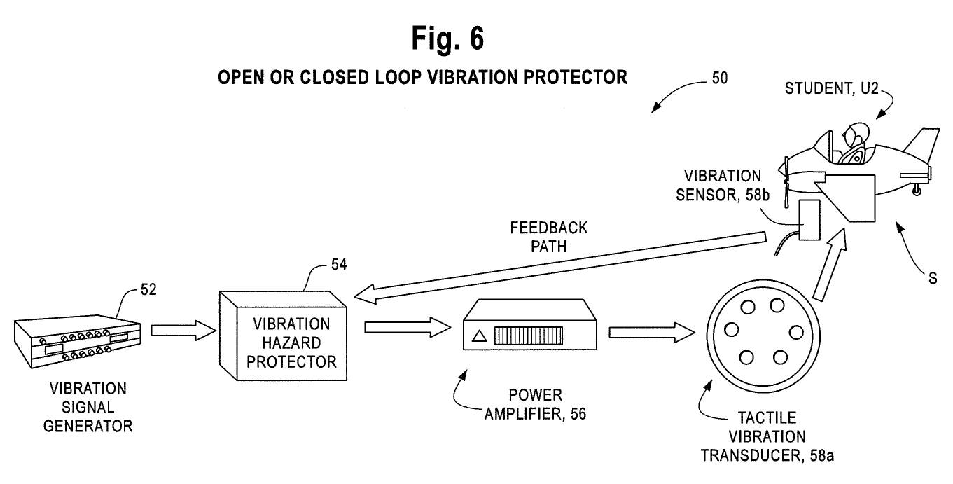

FIG. 6 illustrates a closed loop system 50 which includes a flight simulator S which a student U2 can use for training. In system 50 a vibration signal generator 52 generates vibratory output signals which are coupled to hazard protector 54. Output signals from protector 54 can in turn be coupled to amplifier 56. Outputs from amplifier 56 can be coupled to and drive vibration transducer 58a to enhance the simulation experience. System 50 can be used to provide subsonic tactile cues to the student U2.

A feedback vibration sensor 58b, coupled to simulator S, can provide feedback signals to protector 54. Hazard protector 54 can determine the vibration dosages being received by student U2 based on monitoring signals from sensor 58b. That dosage can be limited to an acceptable level. The system 50 also compensates for resonate behavior of the simulator S. Further, with the feedback path of system 50, no calibration is needed.

From the foregoing, it will be observed that numerous variations and modifications may be effected without departing from the spirit and scope of the invention. It is to be understood that no limitation with respect to the specific apparatus illustrated herein is intended or should be inferred. It is, of course, intended to cover by the appended claims all such modifications as fall within the scope of the claims.

1. An apparatus comprising:
at least one of a headset with at least one audio output transducer, or a loud speaker;
circuitry responsive to one of, acoustic energy associated with audio to be emitted from the transducer, or emitted from the loud speaker, and
a control element coupled at least to the circuitry, the control element limits acoustic energy emitted by the transducer or the loud speaker.

2. An apparatus as in claim 1 where the control element incorporates variable gain circuitry to limit output audio to a predetermined maximum level of acoustic energy.

3. An apparatus as in claim 1 where the control element includes one of a variable gain amplifier, or digital variable gain processing circuitry.

4. An apparatus as in claim 3 where the control element responds to an adjustable gain signal.

5. An apparatus as in claim 1 which includes a sensor of emitted audio.

6. An apparatus as in claim 4 which includes a sound generator coupled to at least one of the headset, or the loud speaker, the sound generator produces the audio to be emitted by one of the output transducer, or, the loud speaker.

7. An apparatus as in claim 6 where at least the circuitry is incorporated into the sound generator.

8. An apparatus as in claim 7 where at least the circuitry and control element comprise executable control software carried on a computer readable medium.

9. An apparatus as in claim 7 where the control element is incorporated into the sound generator.

10. An apparatus as in claim 1 which includes a feedback transducer responsive to audio from the loud speaker.

11. An apparatus as in claim 10 where the circuitry is responsive to an output signal from the transducer.

12. A simulation system comprising:
a vehicular simulator;
a sound generator carried by the simulator, the generator having at least one of an audio output port, or, a vibratory output port; and
at least one of an output audio limiter, or, an output vibratory limiter the limiter adjusts respective output signal magnitudes in accordance with a predetermined criterion.

13. A system as in claim 12 which includes a headset couplable to the output port, the headset has at least one audio output transducer.

14. A system as in claim 13 where the limiter couples adjusted output signals to the headset.

15. A system as in claim 14 where the limiter comprises at least one of limiting circuitry, or, limiting executable software recorded on a computer readable medium.

16. A system as in claim 12 which includes at least one of a loud speaker coupled to the port, or a vibratory transducer coupled to the port.

17. A system as in claim 16 which includes a microphone, an output signal from the microphone is coupled to the limiter.

18. A system as in claim 17 where the limiter, responsive to the output signal, limits audio output from the loud speaker.

19. A system as in claim 12 which includes a vibratory output transducer.

20. A system as in claim 19 where the simulator includes a vibratory sensor.

21. A system as in claim 20 where a signal from the vibratory sensor is coupled to the limiter to limit output vibrations.
